(19) United States
(12) Patent Application Publication
(10) Pub. No.: US 2014/0218892 A1
(43) Pub. Date: Aug. 7, 2014

(54) WIDE EMISSION ANGLE LED PACKAGE WITH REMOTE PHOSPHOR COMPONENT

(71) Applicant: Intematix Corporation, Fremont, CA (US)

(72) Inventors: Charles Edwards, Pleasanton, CA (US); Yi-Qun Li, Danville, CA (US)

(73) Assignee: INTEMATIX CORPORATION, Fremont, CA (US)

(21) Appl. No.: 14/173,759

(22) Filed: Feb. 5, 2014

Related U.S. Application Data
(60) Provisional application No. 61/761,200, filed on Feb. 5, 2013.

(51) Int. Cl. F21K 99/00; H01L 27/15

(52) U.S. Cl. CPC F21K 9/56; H01L 27/156
USPC 362/84; 257/89

(57) ABSTRACT

An improved approach is provided for implementing LED lighting systems and lamps that address the issues identified above. A new type of LED package is disclosed that reduces manufacturing and production costs, while simultaneously allowing for improved thermal management and wide angle light distribution. A self-contained LED package is disclosed that can be mounted as an entire unit onto a lamp platform. The LED package permits the dimensional configuration of the package components to be aligned with desired emission angles. For example, overhangs between phosphor components and circuit boards in the package can be avoided, thereby ensuring that the final lighting system will provide any desired emission angles.

### CROSS-REFERENCE TO RELATED APPLICATIONS

The present application claims the benefit of priority to U.S. Provisional Application Ser. No. 61/761,200, entitled “WIDE EMISSION ANGLE LED PACKAGE WITH REMOTE PHOSPHOR”, filed on Feb. 5, 2013, which is hereby incorporated by reference in its entirety.

### FIELD

This invention relates to wide emission angle packaged LEDs that utilize a remote phosphor component. In particular, although not exclusively, embodiments concern wide emission angle LED packages for solid-state lamps (bulbs) with an omnidirectional emission pattern.

### BACKGROUND

White light generating LEDs, “white LEDs”, are a relatively recent innovation and offer the potential for a whole new generation of energy efficient lighting systems to come into existence. It is predicted that white LEDs could replace filament (incandescent), fluorescent and compact fluorescent light sources due to their long operating lifetimes, potentially many 100,000 of hours, and their high efficiency in terms of low power consumption. It was not until LEDs emitting in the blue/ultraviolet part of the electromagnetic spectrum were developed that it became practical to develop white light sources based on LEDs. As taught, for example in U.S. Pat. No. 5,998,925, white LEDs include one or more phosphor materials, that is photoluminescence materials, which absorb a portion of the radiation emitted by the LED and re-emit radiation of a different color (wavelength). Typically, the LED die generates blue light and the phosphor(s) absorbs a percentage of the blue light and emits yellow light or a combination of green and red light, green and yellow light or yellow and red light. The portion of the blue light generated by the LED that is not absorbed by the phosphor is combined with the light emitted by the phosphor to provide light which appears to the human eye as being nearly white in color.

Due to their long operating life expectancy (>50,000 hours) and high luminous efficacy (70 lumens per watt and higher) high brightness white LEDs are increasingly being used to replace conventional fluorescent, compact fluorescent and incandescent light sources.

Typically in white LEDs the phosphor material is mixed with a light transmissive material such as a silicone or epoxy material and the mixture applied to the light emitting surface of the LED die. It is also known to provide the phosphor material as a layer on, or incorporate the phosphor material within, an optical component (a photoluminescence wavelength conversion component) that is located remote to the LED die (typically physically spatially separated from the LED die). Such arrangements are termed “remote phosphor” arrangements. Advantages of a remotely located phosphor wavelength conversion component are a reduced likelihood of thermal degradation of the phosphor materials and a more consistent color of generated light.

Traditional incandescent light bulbs are inefficient and have life time issues. LED-based technology is moving to replace traditional bulbs and even CFL (Compact Fluorescent Lamp) with a more efficient and longer life lighting solution.

However the known LED-based lamps have difficulty matching the omnidirectional (evenly in all directions) emission characteristics of an incandescent bulb due to the intrinsically highly directional light emission characteristics of LEDs—LED light sources generally have less than 120 degrees of light emission. However, it is desirable for many lamps, such as the most common A-19 lamps (bulb), to radiate light evenly in all directions (omnidrectional). This makes it difficult for white LEDs mounted on a single circuit board to emit light in a similar pattern to a conventional lamp.

Yet another limitation with conventional LED light sources pertains to light blocking. Conventionally, LED lights have a larger base and heat sink design that overhangs the light emitting portion of the LED light, e.g., where the PCB substrate and/or COB packages for the lighting systems are wider than the LED light source. This creates a “shadow area” that prevents light from reaching higher angles of emission from the light, e.g., where light is prevents from travelling at greater than 180 degrees.

Many conventional LED light sources also have packaging that is excessively bulky in nature. This is due in many cases to the overhang of the LED PCB, which prevents many design options for lamps and requires large flat mounting platform in the lamp.

Conventional LED lights also have problems being able to efficiently manage the high levels of heat produced by the lighting system. In part, this due to the fact that LEDs on PCBs have increased thermal resistance because heat must travel from the LED package through to the PCB, and then to the heat sink. This increases the junction temperature of the LEDs, which thereby lowers the overall performance of the LED light.

Another problem pertains to the cost and complexity of conventional LED lights, which tend to be much more expensive as compared to traditional incandescent light bulbs. The relatively higher cost and complexity of LED lights often results from the additional PCB and assembly required to mount the LEDs into a lamp or similar luminaire.

Some combination of these problems exists with all existing technologies used to implement LED lamp applications and luminaires. This makes it difficult for typical LED lights mounted on a single circuit board to emit light in a similar pattern to a conventional lamp. Traditionally packaged LEDs on PCBs or newer Chip On Board solutions all have the above-described limitations/problems in these types of applications.

Therefore, there is a need for an improved approach to implement LED lamps to address these and other problems with conventional technologies.

### SUMMARY

Embodiments of the invention concern an improved approach for implementing LED lighting systems and lamps that address the issues identified above. According to certain embodiments, a new type of LED package is disclosed that reduces manufacturing and production costs, while simultaneously allowing for improved thermal management and wide angle light distribution.

The LED package contains the necessary components, LED chips, substrate (typically a circuit board), and phosphor component to generate light of a desired color, once connected to the appropriate power connection(s). One advantage of the self-contained LED package is that it can be mounted as an entire unit onto a lamp platform. This provides distinct manufacturing advantages over prior approaches where the individual components of the LED engine must be separately and individually assembled within the lighting system.

In addition, the unitary nature of the LED package permits the dimensional configuration of the package components to be aligned with desired emission angles. For example, by considering the LED package as a whole during its design phase, overhangs between phosphor components and circuit boards in the package can be avoided, thereby ensuring that the final lighting system will provide any desired emission angles, e.g. to provide wide angle light distribution as necessary.

An LED package according to some embodiments comprises a substrate, an array of one or more LEDs mounted on the substrate, and a hollow photoluminescence component containing a photoluminescence material, wherein the photoluminescence component is remote from the array of one or more. The photoluminescence component and the substrate are sufficiently matched in dimensions to produce light emission angles from the photoluminescence component at greater than 180 degrees. In some embodiments, the array of LEDS includes either blue or red/blue LEDs with no phosphor deposited directly on the LEDs.

In some embodiments, the LED package comprises a substrate having an outer substrate edge, an array of one or more LEDs mounted on the substrate, and a photoluminescence component comprising a photoluminescence material. The photoluminescence component is remote from and encloses the array of one or more LEDs, and the photoluminescence component has a surface with an outer component edge. The outer component edge is aligned with or extends beyond the outer substrate edge such that the package produces light emission angles from the photoluminescence component at greater than 180 degrees.

The LED package includes thermal pads for thermal conductivity to a heat sink for thermal management. The thermal pad may be implemented as a circular pad on the base of the LED package. The LED package may also include one or more electrical pads to provide electrical connections into and out of the package. The circular LED package is therefore integrally developed with large thermal connection(s) on its base, along with electrical connections that are also preferably also on the base. In some embodiments, the electrical connections may be on the base, side and/or on top of the package. The electrical connections in some embodiments include an annular connector for the power connection and a circular connector for ground connection as well as for the thermal pad. A benefit of an annular connector is that this avoids issues of angular orientation of the LED package when incorporating the LED package into a lighting system or lamp. In some embodiments, the base of the LED package only includes the thermal contact pad, and does not include connection pads for power and ground. Instead, wire “pig tail” connections are provided for electrical connection to/from the LED package.

The LED package therefore allows the remote phosphor component and circular LED array to be integrated into a compact light source. The result of this integration is a compact “mini light bulb” or “LED filament” that can be directly mounted to a lamp or luminaire assembly without requiring an additional PCB or similar support structure. This permits the lamp to be manufactured in a very efficient and cost effective way, since the individual components of the LED package do not need to be separately assembled onto the lamp. Instead, the entirety of the LED package (including all of its constituent components) can be mounted as a single unit directly to the lamp.

In some embodiments, the diameter of the remote phosphor component is substantially the same as the diameter of the circular LED array/substrate. This minimization or elimination of overhang between the circular LED array/circuit board and the remote phosphor component allows for a very wide angle of light emissions. In some embodiments, light emission angles can be produced that are greater than 180 degrees, and generally greater than 250 degrees. This permits the LED package to be easily assembled into a lamp or luminarie, while still providing for the widest possible light pattern without a shadow area.

The footprint and heat sink base of the LED package is configured to smoothly integrate the LED package onto a pedestal of the lamp platform, making the optical design and thermal design easier and simpler. The pedestal in some embodiments is a frusto-conical thermally conductive pillar upon which the LED package is mounted to a base of the lamp platform. A thermal pad on the LED package permits easy thermal connection to a heat sink (e.g. combination of pedestal and base) on the lamp. For example, a simple and efficient “reflow” approach can be taken to attach the thermal pad on the LED package to the upper surface of the pedestal.

Conventional LED lamps often have problems being able to efficiently manage the high levels of heat produced by the lighting system, due at least in part to the fact that conventional lamps mount packaged LEDs onto PCBs which increases the thermal resistance, which causes increases in junction temperature of the LEDs. In some embodiments of the invention, the thermal connection between the thermal pad of the LED package to the thermally conductive pedestal permits a direct thermal connection that reduces thermal resistance between the components, thereby allowing for more efficient thermal management of the lamp.

The LED package comprises a hollow photoluminescence wavelength conversion component that includes one or more photoluminescence materials. In some embodiments, the photoluminescence materials comprise phosphors. Examples of photoluminescence materials include phosphor materials and quantum dots.

The lamp that includes the LED package can comprise a light diffusive envelope or cover. The cover can comprise a glass or a light transmissive polymer such as a polycarbonate, acrylic, PET or PVC that incorporates or has a layer of light diffusive (scattering) material. Example of light diffusive materials include particles of Zinc Oxide (ZnO), titanium dioxide (TiO₂), barium sulfate (BaSO₄), magnesium oxide (MgO), silicon dioxide (SiO2) or aluminum oxide (Al₂O₃).

A further advantage of LED packages in accordance with the invention is that their light emission resembles a filament of a conventional incandescent light bulb.

The photoluminescence material can be applied in different ways to the remote phosphor component. In one embodiment, the photoluminescence material is homogeneously distributed throughout the volume of the component. Such components can be conveniently fabrication by injection molding. In an alternate approach, the photoluminescence material is coated onto a light transmissive component that acts as a substrate for the photoluminescence material. Any suitable approach can be used to deposit the photoluminescence material onto the light transmissive cover. Suitable deposition techniques in some embodiments include, for example, spraying, painting, spin coating, screen printing or including the photoluminescence material on a sleeve that is placed adjacent to the light transmissive cover.

Transparent encapsulation may be used to surround the LED chips within the LED package to provide mechanical protection of the bond wires used to connect the LED chips to the substrate. In one approach, a single layer of encapsulant is used to encapsulate all of the LED chips within the package. In an alternate approach, each of the LED chips is individually covered with the encapsulant. In addition and or alternatively a solid optical medium can also be used to entirely fill the interior of the phosphor component, where the solid optical medium allows the interior of the wavelength conversion component to comprise a material possessing an index of refraction that more closely matches the index of refraction for the wavelength conversion component and/or the LED chips. This permits light to be emitted to, within, and/or through the interior volume of the wavelength conversion component without having to incur losses caused by excessive mismatches in the indices of refraction for an air interface. The optical medium may be selected of a material, e.g. silicone, to generally fall within or match the materials of the wavelength conversion component and/or the LED chips.

The invention is suitably applicable to any type of lamp designation, including General Service (A, mushroom), High Wattage General Service (PS—pear shaped), Decorative (B—candle, CA—twisted candle, BA—bent-tip candle, F—flame, P—fancy round, G—globe), Reflector (R), Parabolic aluminized reflector (PAR) and Multifaceted reflector (MR) type lamps. A particularly useful application of the invention is for implementation of A-19 type lamps, particularly for Energy Star compliant A-19 lamps that have certain emission angle requirements which can be met by the wide-angle emissions capabilities of embodiments of the invention.

Certain embodiments of the invention also concern methods of manufacturing the LED package and/or a lamp in which the LED package is assembled.

The process includes steps for assembling the LED chips onto a substrate such as an MCPCB (metal core printed circuit board). The LED chips are mounted (e.g. as a circular array) on a circular shaped substrate on a respective thermal pad on the upper surface of the substrate. The LED chips can be mounted to the thermal pads by soldering, reflow soldering, flip chip bonding or other techniques known in the art. Next, the LED chips are electrically connected to the substrate by wire bonding or other techniques such as flip chip bonding in a desired electrical configuration.

With regard to manufacture of an LED package in which each LED chip is individually encapsulated, a molding approach can be used to form an encapsulation over each of the LED chips. A mold is provided which has appropriately sized recesses that correspond to the position of each LED chip. The mold is positioned such that each interior recess is located as necessary relative to its corresponding LED chip. Next, the encapsulant (which may be composed of an index matching gel or liquid material) is poured through mold filling ports into the interior recesses of the mold. A curing process is then employed to cure the index matching gel or liquid material into its final solid form, e.g. by application of heat or UV light. The mold is removed after the encapsulant has been cured. This leaves the encapsulant individually encapsulating each of the LED chips. The phosphor component is then prepared for attachment to the substrate containing the LEDs. The phosphor component may include a lip that is configured to match the exterior profile of the substrate. An adhesive material can be used to affix the phosphor component to the circuit board. In some embodiments, the adhesive material forms a water-tight and hermetic seal that protects the interior of the LED package from exterior environmental contamination and/or degradation.

With regard to manufacture of an LED package in which a solid optical medium fills the interior volume of the phosphor component, a mold is provided which has a recess that exactly corresponds to the interior surface of the phosphor component. The mold is properly positioned on the circuit board over the LED chips, and the material of the solid optical component (which may be composed of an index matching gel or liquid material) is poured through the mold filling ports into the interior recess of the mold. A curing process is then employed to cure the index matching gel or liquid material into its final solid form, e.g. by application of heat or UV light. The mold is removed after the encapsulant has been cured. The phosphor component is then positioned to seat onto the circuit board and to surround the optical medium (component). If the solid optical medium has been molded with exactly the correct dimensions, then there should not be any air pockets/interfaces between the optical medium and the phosphor component. If, however, manufacturing tolerances have resulted in the existence of any such air pockets/interfaces, then additional index matching gel may be introduced into the interior of the component to eliminate the air pockets/interfaces. The phosphor component is then affixed to the circuit board, where an adhesive material is used to affix the phosphor component to the circuit board. In some embodiments, the adhesive material forms a water-tight and hermetic seal that protects the interior of the LED package from exterior environmental contamination and/or degradation.

Further details of aspects, objects, and advantages of the invention are described below in the detailed description, drawings and claims. Both the foregoing general description and the following detailed description are exemplary and explanatory, and are not intended to be limiting as to the scope of the invention.

### BRIEF DESCRIPTION OF THE DRAWINGS

In order that the present invention is better understood, LED packages, LED-based lamps and methods of manufacture in accordance with embodiments of the invention will now be described, by way of example only, with reference to the accompanying drawings in which:

FIG. 1A is a schematic sectional view of a LED package in accordance with an embodiment of the invention;

FIG. 1B is underside view of the LED package of FIG. 1A in a direction ‘A’;

FIG. 2 is an schematic partial sectional view of an LED-based lamp utilizing an LED package in accordance with an embodiment of the invention;

FIG. 3 is a schematic partial sectional view of the LED-based lamp of FIG. 2 indicating light emission;

FIG. 4A is a schematic sectional view of a LED package in accordance with an embodiment of the invention;

FIG. 4B is underside view of the LED package of FIG. 4A in a direction ‘A’;

FIG. 5 is a schematic sectional view of a LED package in accordance with an embodiment of the invention;

FIG. 6A-6F illustrates an approach for manufacturing the LED package of FIG. 1 in accordance with an embodiment of the invention; and

FIG. 7A-7G illustrates an approach for manufacturing the LED package of FIG. 5 in accordance with an embodiment of the invention;

FIG. 8A is a perspective view of a phosphor component;

FIG. 8B is a schematic sectional view of a LED package in accordance with an embodiment of the invention utilizing the phosphor component of FIG. 8A;

FIG. 9 is an schematic partial sectional view of an LED-based candle lamp utilizing the LED package of FIG. 8B;

FIG. 10 is a perspective view of a further phosphor component;

FIG. 11 is a side view of the phosphor component of FIG. 10; and

FIG. 12 is a schematic partial sectional view of an LED reflector lamp utilizing an LED package in accordance with an embodiment of the invention.

### DETAILED DESCRIPTION

The invention provide an improved approach for implementing LED lighting systems that address the issues identified above. According to certain embodiments, a new type of LED light package is disclosed that reduces manufacturing and production costs, while simultaneously allowing for improved thermal management and wide angle light distribution.

Improved lamps (light bulbs) according to the invention are available in a number of forms, and may be standardly referenced by a combination of letters and numbers. The letter designation of a lamp typically refers to the particular shape of type of that lamp, such as General Service (A, mushroom), High Wattage General Service (PS—pear shaped), Decorative (B—candle, CA—twisted candle, BA—bent-tip candle, F—flame, P—fancy round, G—globe), Reflector (R), Parabolic aluminized reflector (PAR) and Multifaceted reflector (MR). The number designation refers to the size of a lamp, often by indicating the diameter of a lamp in units of eighths of an inch. Thus, an A-19 type lamp refers to a general service lamp (bulb) whose shape is referred to by the letter “A” and has a maximum diameter two and three eights of an inch. As of the time of filing of this patent document, the most commonly used household “light bulb” is the lamp having the A-19 envelope, which in the United States is commonly sold with an E26 screw base.

There are various standardization and regulatory bodies that provide exact specifications to define criteria under which a manufacturer is entitled to label a lighting product using these standard reference designations. With regard to the physical dimensions of the lamp, ANSI provides the specifications (ANSI C78.20-2003) that outline the required sizing and shape by which compliance will entitle the manufacture to permissibly label the lamp as an A-19 type lamp. Besides the physical dimensions of the lamp, there may also be additional specifications and standards that refer to performance and functionality of the lamp. For example in the United States the US Environmental Protection Agency (EPA) in conjunction with the US Department of Energy (DOE) promulgates performance specifications under which a lamp may be designated as an “ENERGY STAR” compliant product, e.g. identifying the power usage requirements, minimum light output requirements, luminous intensity distribution requirements, luminous efficacy requirements and life expectancy.

The problem is that the disparate requirements of the different specifications and standards create design constraints that are often in tension with one another. For example, the A-19 lamp is associated with very specific physical sizing and dimension requirements, which is needed to make sure A-19 type lamps sold in the marketplace will fit into common household lighting fixtures. However, for an LED-based replacement lamp to be qualified as an A-19 replacement by ENERGY STAR, it must demonstrate certain performance-related criteria that are difficult to achieve with a solid-state lighting product when limited to the form factor and size of the A-19 light lamp.

For example, with regard to the luminous intensity distribution criteria in the ENERGY STAR specifications, for an LED-based replacement lamp to be qualified as an A-19 replacement by ENERGY STAR it must demonstrate an even (+/−20%) luminous emitted intensity over 270° with a minimum of 5% of the total light emission above 270°. The issue is that LED replacement lamps need electronic drive circuitry and an adequate heat sink area; in order to fit these components into an A-19 form factor, the bottom portion of the lamp (envelope) is replaced by a thermally conductive housing that acts as a heat sink and houses the driver circuitry needed to convert AC power to low voltage DC power used by the LEDs. A problem created by the housing of an LED lamp is that it blocks light emission in directions towards the base as is required to be ENERGY STAR compliant. As a result many LED lamps lose the lower light emitting area of traditional bulbs and become directional light sources, emitting most of the light out of the top dome (180° pattern) and virtually no light downward since it is blocked by the heat sink (body), which frustrates the ability of the lamp to comply with the luminous intensity distribution criteria in the ENERGY STAR specification.

Currently LED replacement lamps are considered too expensive for the general consumer market. Typically an A-19, 60 W replacement LED lamp costs many times the cost of an incandescent bulb or compact fluorescent lamp. The high cost is due to the complex and expensive construction and components used in these lamps.

Embodiments of the invention are directed to an improved type of self-contained LED package that provide for improved light distribution and thermal management, while also allowing for simplified and efficient manufacture of an LED-based lamp.

The LED package contains the necessary LED components, circuit board, and phosphor components to generate light of a desired color, once connected to the appropriate power connection(s). One advantage of the self-contained LED package is that it can be mounted as an entire unit onto a lamp platform. This provides distinct manufacturing advantages over prior approaches where the individual components of the LED light must be separately and individually assembled within the lighting system.

In addition, the unitary nature of the LED package permits the dimensional configuration of the package components to be aligned with desired illumination angles. For example, by considering the LED package as a whole during its design phase, excessive overhangs between phosphor components and circuit boards in the package can be avoided, thereby ensuring that the final lighting system will provide any desired illumination angles, e.g., to provide wide angle light distribution as necessary.

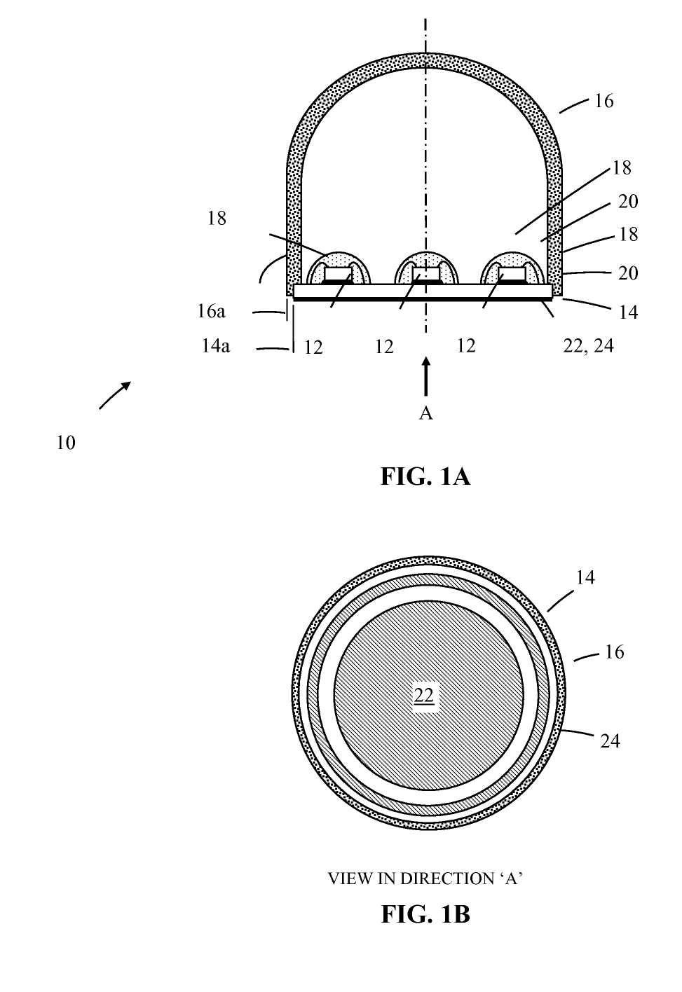

An LED package 10 in accordance with embodiments of the invention is now described with reference to FIGS. 1A and 1B. The LED package 10 comprises an array of one or more LED chips 12 mounted onto a substrate 14, with a remote phosphor component 16 surrounding the array of LED chips 12.

In the current embodiment, it is noted that the array consists of either blue or red/blue LEDs with no phosphor deposited directly on the LED chips. Examples of suitable substrates include Metal Core Printed Circuit Boards (MCPCB), Fire Retardant PCB such as FR4 PCB, Plastic Leadless Chip Carrier (PLCC), Ceramic Leadless Chip Carrier (CLCC), Low Temperature Co-fired Ceramic (LTCC), as well as Metal Ceramic technologies that can provide high thermal conductivity LED packaging in any suitable size and shape. Transparent encapsulation 18 may be used to surround the LED chips 12. The LED chips 12 are mounted onto the substrate 14, which may be implemented, for example, as a MCPCB. As is known a MCPCB comprises a layered structure composed of a metal core base, typically aluminum, a thermally conducting/electrically insulating dielectric layer and a copper circuit layer for electrically connecting electrical components in a desired circuit configuration. Chip wire bonds 20 connect the LED chips 12 to connectors on the circuit board 14.

Thermal and electrical pads 22, 24 are located on the bottom of the LED package 10 to allow for thermal management and electrical connections of the LED chips. The circular LED package 10 is therefore integrally developed with large thermal connection(s) on its base, along with electrical connections that are also preferably also on the base. In some embodiments, the electrical connections may be on the base, side and/or on top of the package. The electrical connections in the current embodiment include an annular electrical connector 24 for the power connection Vcc and a circular connector 22 for electrical ground Gnd connection as well as for the thermal pad.

The LED package 10 allows the remote phosphor cover 16 and circular LED array to be integrated into a compact light source. The result of this invention is a compact “mini light bulb”, “light engine” or “LED filament” that can be directly mounted to a lamp or luminaire assembly without requiring an additional PCB or similar support structure. This permits the lamp to be manufactured in a very efficient and cost effective way, since the individual components of the LED package do not need to be separately assembled onto the lamp. Instead, the entirety of the LED package (including all of its constituent components) can be mounted as a single unit directly to the lamp.

In addition, by considering the LED package 10 as a whole during its design phase, excessive overhangs between phosphor components and circuit boards in the package can be avoided. Here, it can be seen that the outer edge 14a of the circuit board 14 does not overhang the outer edge 16a of the remote phosphor component 16. Instead, it is the outer edge 16a of the remote phosphor component 16 that extends beyond the outer edge 14a of the circuit board 14. This ensures that the final lighting system will provide any desired illumination angles, e.g., to provide wide angle light distribution as necessary.

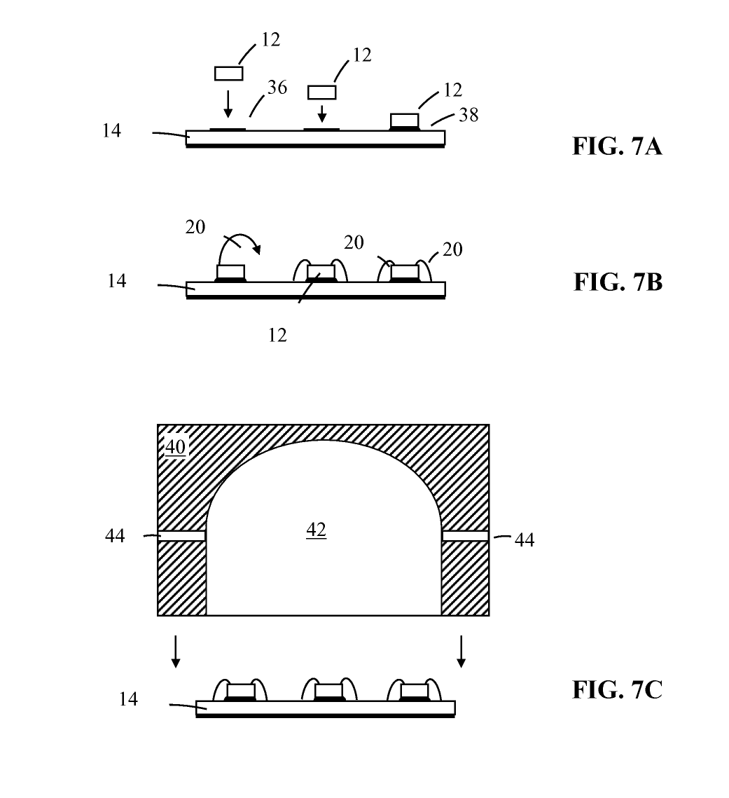

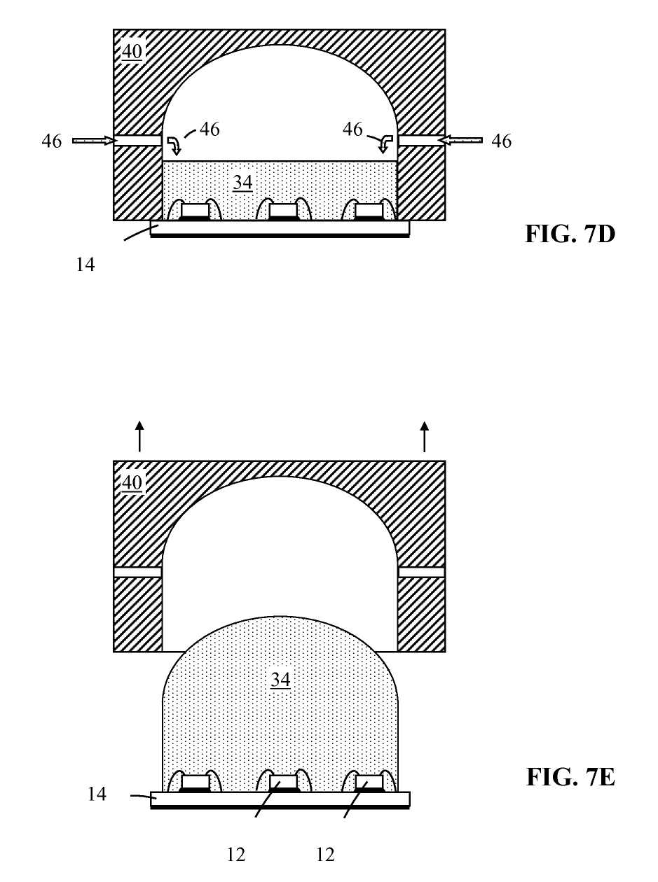

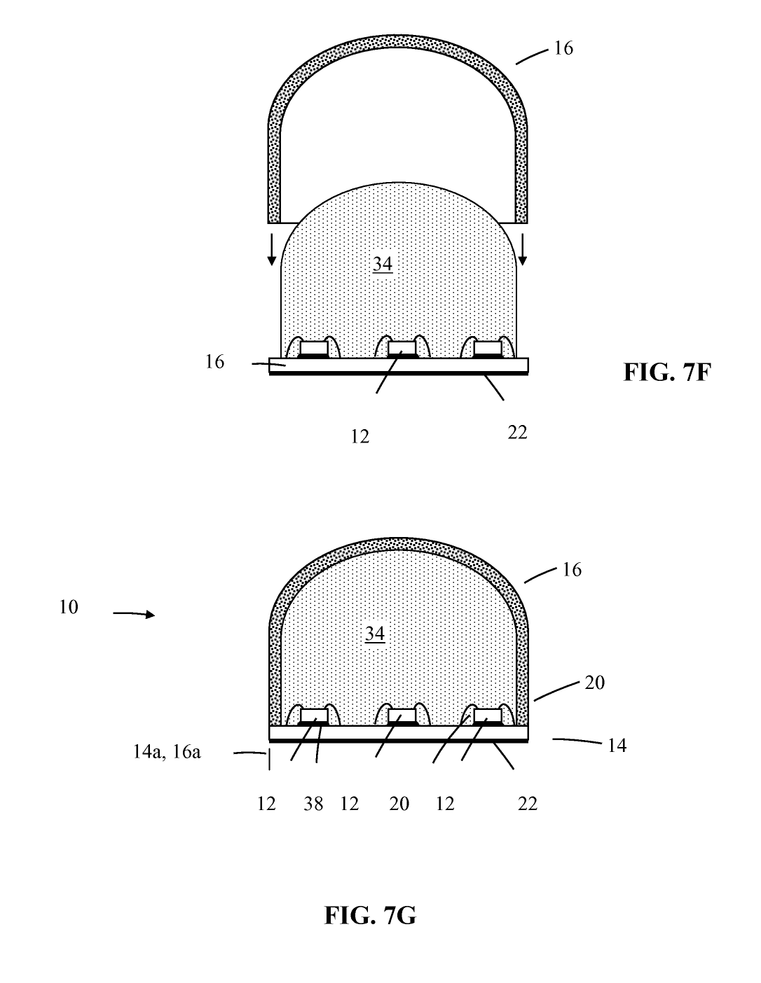

It is noted that in some embodiments of the invention, the outer edge 16a of the remote phosphor component 16 is aligned with the outer edge 14a of the circuit board 14, rather than extending beyond the outer edge 14a of the substrate/circuit board 14 (e.g., as shown in FIG. 7G). Alternative embodiments may not require the outer edge 16a of the component 16 to uniformly align with or extend beyond the outer edge 14a of the substrate/circuit board 14. This situation may exist, for example, if a relatively small portion of the substrate/circuit board 14 extends outward past the edge 16a of the component 16.

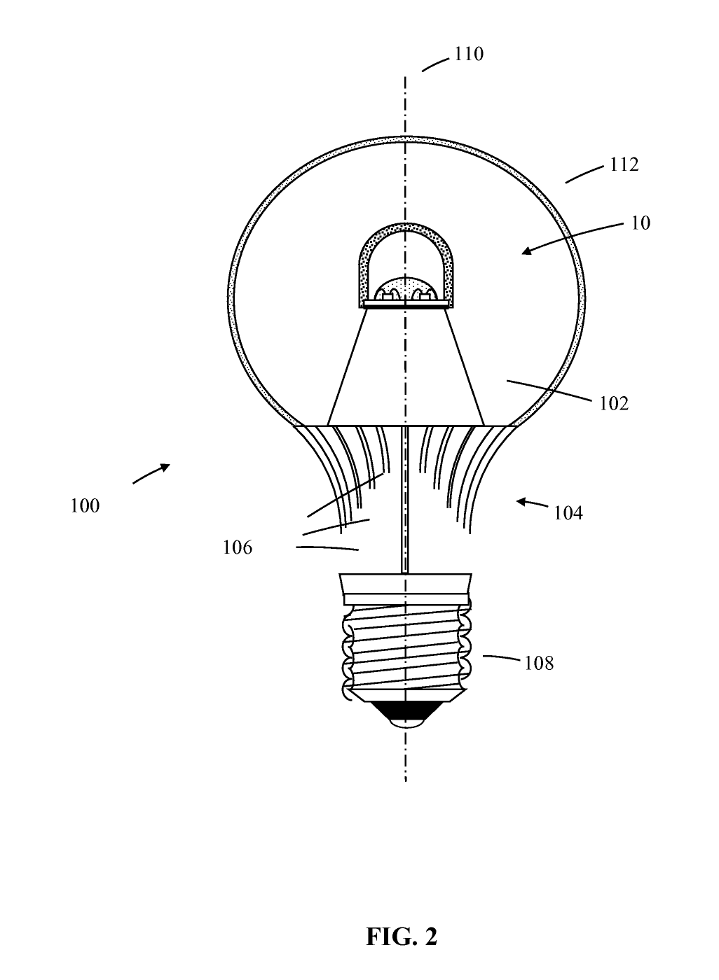

FIG. 2 illustrates an LED-based lamp 100 in accordance with embodiments of the invention. This figure shows a schematic partial sectional view of the lamp 100 having the LED package 10 mounted thereon. The footprint and heat sink base of the package 10 is designed to smoothly integrate the LED package 10 onto the pedestal 102 of the lamp 100, making the optical design and thermal design easier and simpler. The Pedestal 102 is a frustoconical thermally conductive pillar upon which the LED package 10 is mounted in thermal communication with.

The lamp 100 is configured in come embodiments for operation with a 110V (r.m.s.) AC (60 Hz) mains power supply as is found in North America and is intended for use as an ENERGY STAR compliant replacement for an A-19 incandescent light bulb. The lamp 100 comprises a generally conical shaped thermally conductive body 104. The outer surface of the body 104 generally resembles a frustrum of a cone; that is, a cone whose apex (vertex) is truncated by a plane that is parallel to the base (i.e. substantially frustoconical). The body 104 is made of a material with a high thermal conductivity (typically ≧150 Wm⁻¹K⁻¹, preferably ≧200 Wm⁻¹K⁻¹) such as for example aluminum (≈250 Wm⁻¹K⁻¹), an alloy of aluminum, a magnesium alloy, a metal loaded plastics material such as a polymer, for example an epoxy. Conveniently the body 104 can be die cast when it comprises a metal alloy or molded, by for example injection molding, when it comprises a metal loaded polymer.

A plurality of latitudinal radially extending heat radiating fins (veins) 106 is circumferentially spaced around the outer curved surface of the body 104. Since the lamp is intended to replace a conventional incandescent A-19 light bulb the dimensions of the lamp are selected to ensure that the device will fit a conventional lighting fixture. The body 104 can further comprise a coaxial cylindrical cavity (not shown) that extends into the body from the truncated apex the body for housing rectifier or other driver circuitry for operating the lamp.

The lamp 100 further comprises an E26 connector cap (Edison screw lamp base) 108 enabling the lamp to be directly connected to a mains power supply using a standard electrical lighting screw socket. It will be appreciated that depending on the intended application other connector caps can be used such as, for example, a double contact bayonet connector (i.e. B22d or BC) as is commonly used in the United Kingdom, Ireland, Australia, New Zealand and various parts of the British Commonwealth or an E27 screw base (Edison screw lamp base) as used in Europe. The connector cap 108 is mounted to the truncated apex of the body 104.

As noted above, the LED package 10 has one or more solid-state light emitters (e.g. LED chips 12) that are mounted on a circular substrate 14, where the substrate 16 comprises a circular MCPCB.

The thermal pad on the LED package permits easy thermal connection to a heat sink on the lamp 100. For example, a simple and efficient “reflow” approach can be taken to attach the thermal pad on the LED package 10 to the upper surface of the conical pedestal 130.

As noted above, conventional LED lights often have problems being able to efficiently manage the high levels of heat produced by the lighting system. In part, this due to the fact that conventional lamps mount packaged LED chips onto PCBs this increases the thermal resistance, which causes increases in junction temperature of the LEDs. In contrast in the current embodiment in which the LED chips are mounted in direct thermal communication with the substrate, the thermal connection between the thermal pad of the LED package to the thermally conductive pedestal 102 reduces the thermal resistance between the components, thereby allowing for more efficient thermal management of the lamp 100.

In some embodiment, each LED chip 12 can comprise a gallium nitride-based blue light (and/or red and/or red/blue) emitting LED that is operable to generate blue light with a dominant wavelength of 455 nm-465 nm. The LED chips can be configured as a circular array and oriented such that their principle emission axis is parallel with the axis 110 of the lamp 100. A light reflective coating or can be provided on the upper surface of the MCPCB 14 to maximize light emission from the lamp.

The LED package 10 within the lamp 100 comprises a photoluminescence wavelength conversion component 16 that includes one or more photoluminescence materials. In some embodiments, the photoluminescence materials comprise phosphors. For the purposes of illustration only, the following description is made with reference to photoluminescence materials embodied specifically as phosphor materials. However, the invention is applicable to any type of photoluminescence material, such as either phosphor materials or quantum dots. A quantum dot is a portion of matter (e.g. semiconductor) whose excitons are confined in all three spatial dimensions that may be excited by radiation energy to emit light of a particular wavelength or range of wavelengths.

The one or more phosphor materials can include an inorganic or organic phosphor such as for example silicate-based phosphor of a general composition A₃Si(O,D)₅ or A₂Si(O,D)₄ in which Si is silicon, O is oxygen, A includes strontium (Sr), barium (Ba), magnesium (Mg) or calcium (Ca) and D includes chlorine (Cl), fluorine (F), nitrogen (N) or sulfur (S). Examples of silicate-based phosphors are disclosed in United States patents U.S. Pat. No. 7,575,697 B2 “Silicate-based green phosphors”, U.S. Pat. No. 7,601,276 B2 “Two phase silicate-based yellow phosphors”, U.S. Pat. No. 7,655,156 B2 “Silicate-based orange phosphors” and U.S. Pat. No. 7,311,858 B2 “Silicate-based yellow-green phosphors”. The phosphor can also include an aluminate-based material such as is taught in co-pending patent application US2006/0158090 A1 “Novel aluminate-based green phosphors” and patent U.S. Pat. No. 7,390,437 B2 “Aluminate-based blue phosphors”, an aluminum-silicate phosphor as taught in co-pending application US2008/0111472 A1 “Aluminum-silicate orange-red phosphor” or a nitride-based red phosphor material such as is taught in co-pending United States patent application US2009/0283721 A1 “Nitride-based red phosphors” and International patent application WO2010/074963 A1 “Nitride-based red-emitting in RGB (red-green-blue) lighting systems”. It will be appreciated that the phosphor material is not limited to the examples described and can include any phosphor material including nitride and/or sulfate phosphor materials, oxy-nitrides and oxy-sulfate phosphors or garnet materials (YAG).

Quantum dots can comprise different materials, for example cadmium selenide (CdSe). The color of light generated by a quantum dot is enabled by the quantum confinement effect associated with the nano-crystal structure of the quantum dots. The energy level of each quantum dot relates directly to the size of the quantum dot. For example, the larger quantum dots, such as red quantum dots, can absorb and emit photons having a relatively lower energy (i.e. a relatively longer wavelength). On the other hand, orange quantum dots, which are smaller in size can absorb and emit photons of a relatively higher energy (shorter wavelength). Additionally, daylight panels are envisioned that use cadmium free quantum dots and rare earth (RE) doped oxide colloidal phosphor nano-particles, in order to avoid the toxicity of the cadmium in the quantum dots.

Examples of suitable quantum dots include: CdZnSeS (cadmium zinc selenium sulfide), CdₓZn₁₋ₓSe (cadmium zinc selenide), CdSeₓS₁₋ₓ (cadmim selenium sulfide), CdTe (cadmium telluride), CdTeₓS₁₋ₓ (cadmium tellurium sulfide), InP (indium phosphide), InₓGa₁₋ₓP (indium gallium phosphide), InAs (indium arsenide), CuInS₂ (copper indium sulfide), CuInSe₂ (copper indium selenide), CuInSₓSe₂₋ₓ (copper indium sulfur selenide), CuInₓGa₁₋ₓS₂ (copper indium gallium sulfide), CuInₓGa₁₋ₓSe₂ (copper indium gallium selenide), CuInₓAl₁₋ₓSe₂ (copper indium aluminum selenide), CuGaS₂ (copper gallium sulfide) and CuInS₂ₓZnS₁₋ₓ (copper indium selenium zinc selenide).

The quantum dots material can comprise core/shell nano-crystals containing different materials in an onion-like structure. For example, the above described exemplary materials can be used as the core materials for the core/shell nano-crystals.

The optical properties of the core nano-crystals in one material can be altered by growing an epitaxial-type shell of another material. Depending on the requirements, the core/shell nano-crystals can have a single shell or multiple shells. The shell materials can be chosen based on the band gap engineering. For example, the shell materials can have a band gap larger than the core materials so that the shell of the nano-crystals can separate the surface of the optically active core from its surrounding medium.

In the case of the cadmiun-based quantum dots, e.g. CdSe quantum dots, the core/shell quantum dots can be synthesized using the formula of CdSe/ZnS, CdSe/CdS, CdSe/ZnSe, CdSe/CdS/ZnS, or CdSe/ZnSe/ZnS. Similarly, for CuInS₂ quantum dots, the core/shell nanocrystals can be synthesized using the formula of CuInS₂/ZnS, CuInS₂/CdS, CuInS₂/CuGaS₂, CuInS₂/CuGaS₂/ZnS and so on.

The lamp 100 can further comprise a light diffusive envelope or cover 112 mounted to the base of the body 104. The cover 112 can comprise a glass or a light transmissive polymer such as a polycarbonate, acrylic, PET or PVC that incorporates or has a layer of light diffusive (scattering) material. Example of light diffusive materials include particles of Zinc Oxide (ZnO), titanium dioxide (TiO₂), barium sulfate (BaSO₄), magnesium oxide (MgO), silicon dioxide (SiO₂) or aluminum oxide (Al₂O₃).

In operation the LEDs 12 in the package 10 generate blue excitation light a portion of which excite the photoluminescence material within the wavelength conversion component 16 which in response generates by a process of photoluminescence light of another wavelength (color) typically yellow, yellow/green, orange, red or a combination thereof. The portion of blue LED generated light combined with the photoluminescence material generated light gives the lamp an emission product that is white in color.

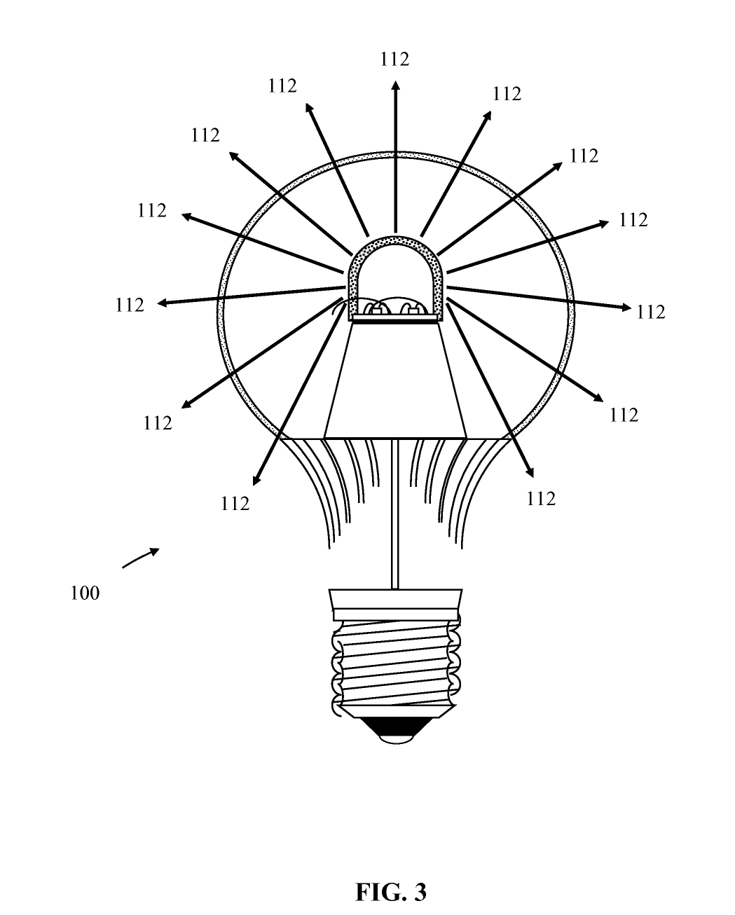

In some embodiments, the internal diameter of the remote phosphor component 16 is substantially the same as the diameter of the circular LED array/substrate 14. As illustrated in FIG. 3 this minimization or elimination of an overhang between the circular LED array/circuit board and the remote phosphor component allows for a very wide angle of light emissions. In some embodiments, light emission angles can be produced that are greater than 180 degrees, and generally greater than 250 degrees. This permits the LED package to be easily assembled into a lamp or luminarie, while still providing for the widest possible light pattern without a shadow area. In some embodiment, the lamp 100 can therefore produce light emission angles that are greater than 180 degrees, and generally greater than 250 degrees. This permits the LED package 10 to be easily assembled into a lamp or luminarie, while still providing for the widest possible light pattern without a shadow area.

A further advantage of photoluminescence wavelength conversion components in accordance with the invention is that their light emission resembles a filament of a conventional incandescent light bulb.

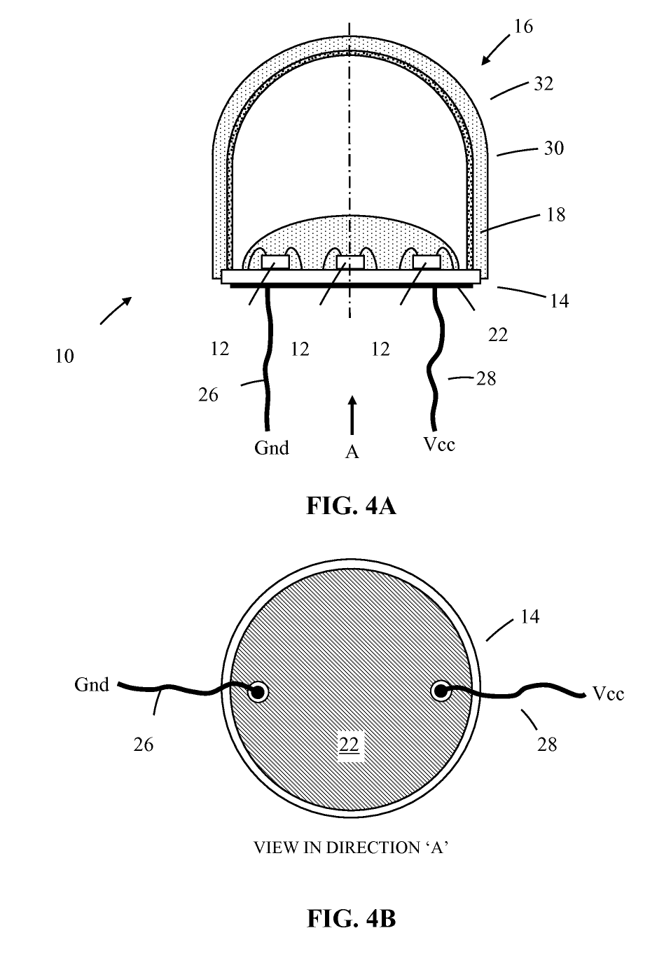

FIG. 4A-4B illustrates alternate implementation approach(es) that can be taken for the LED package 10. In this embodiment, the base of the LED package only includes the thermal contact pad, and does not include connection pads for power Vcc and ground Gnd. Instead, wire “pig tail” connections or leads 26 are provided for electrical connection to/from the LED package 10.

In addition, a single layer of encapsulant 18 is used to encapsulate all of the LED chips 12. This is in contrast to the approach of FIG. 1 in which each of the LED chips 12 is individually covered with encapsulant 18.

The photoluminescence material can be applied in different ways to the remote phosphor component 16. In the approach of FIG. 1, the photoluminescence material is homogeneously distributed throughout the volume of the component 16 during manufacture of the component 16. In the approach of FIG. 4, the photoluminescence material 30 is coated as a layer onto a transparent component 32 that acts as a light transmissive substrate for the photoluminescence material. Any suitable approach can be used to deposit the photoluminescence material onto the light transmissive component 32. Suitable deposition techniques in some embodiments include, for example, spraying, painting, spin coating, screen printing or including the photoluminescence material on a sleeve that is placed adjacent to the light transmissive component 32.

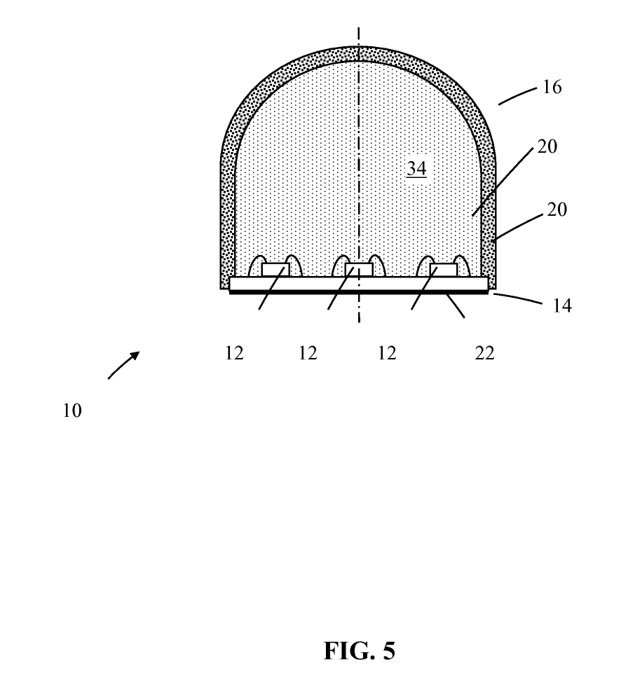

FIG. 5 illustrates alternate an implementation approach that can be taken to implement the LED package 10. In this embodiment, the quantum efficiency of the LED package 10 is improved by minimizing or eliminating air interface losses due to any air gaps between the phosphor component 16 and the LED chips 12. Such air interfaces exist, for example, in the embodiments of FIGS. 1 and 4. In these figures, since there is a mismatch between the index of refraction of the material of the wavelength conversion component 16 and the index of refraction of the air within the interior volume of the LED package, this mismatch in the indices of refraction for the interfaces between air and the lamp components can cause a significant portion of the light emitted by the LED chips 12 to be lost in the form of heat generation. As a result, lesser amounts of light and excessive amounts of heat are generated for a given quantity of input power. This inefficiency causes larger amounts of power to be used to produce a given amount of emitted light. This type of inefficiency also causes lamp designs to require larger and bulkier thermal management structures to handle the amount of heat produced by the LED lamp.

To address this issue, the embodiment of FIG. 5 utilizes an optical medium 34 within the interior volume of the photoluminescence component 16. The optical medium 34 ensures that the interior of the wavelength conversion component 16 comprises a material having an index of refraction that more closely matches the index of refraction for the wavelength conversion component 16 and/or the LEDs chips 12. This permits light to be emitted to, within, and/or through the interior volume of the wavelength conversion component 16 without having to incur losses caused by excessive mismatches in the indices of refraction for an air interface.

The composition of the optical medium 34, which is typically solid, is selected to have an index of refraction that generally matches the index of refraction for the wavelength conversion component 16 and/or the LEDs 12. For example, the wavelength conversion component 16 may comprise a silicone or polymer base material having an index of refraction in the general range of 1.4 to 1.6. The encapsulant/potting material 18 for many LED package components is often made of materials (such as silicone) having an index of refraction in a similar range of 1.4 to 1.6. The optical medium 34 may be selected of a material, e.g. silicone, to generally fall within or match this range. This high refractive index material in the LED package facilitates effective blue light extraction from the LED, e.g. increasing performance by 20% or more. The use of a silicone or similar polymer in the center of this shape that couples from the LED to the outer remote phosphor also serves for improving light extraction from the LED. This facilitates the use of the arrays of LEDs without requiring clear lenses or domes on each LED. Light extraction can be directly implemented in this embodiment of the invention, decreasing the cost of the LED packaging by integrating the light extraction and remote phosphor features into a single device.

In operation, LED light is produced by the array of LEDs 12, which is then emitted through the optical medium 34 to the wavelength conversion layer to further emit photoluminescence light. The photoluminescence light is emitted in all directions, including back within the interior volume filled with the optical medium 34 within the wavelength conversion component 16. Since the boundaries between the array of LEDs 20, the solid optical component 42, and the wavelength conversion layer 22 all generally match, this greatly reduces the amount of light that is lost due to the light coupling effects of the solid optical component 42. This permits the lamp to significantly increase the amount of light output for a given quantity of input power. This also means that much less heat is produced by the loss of the light.

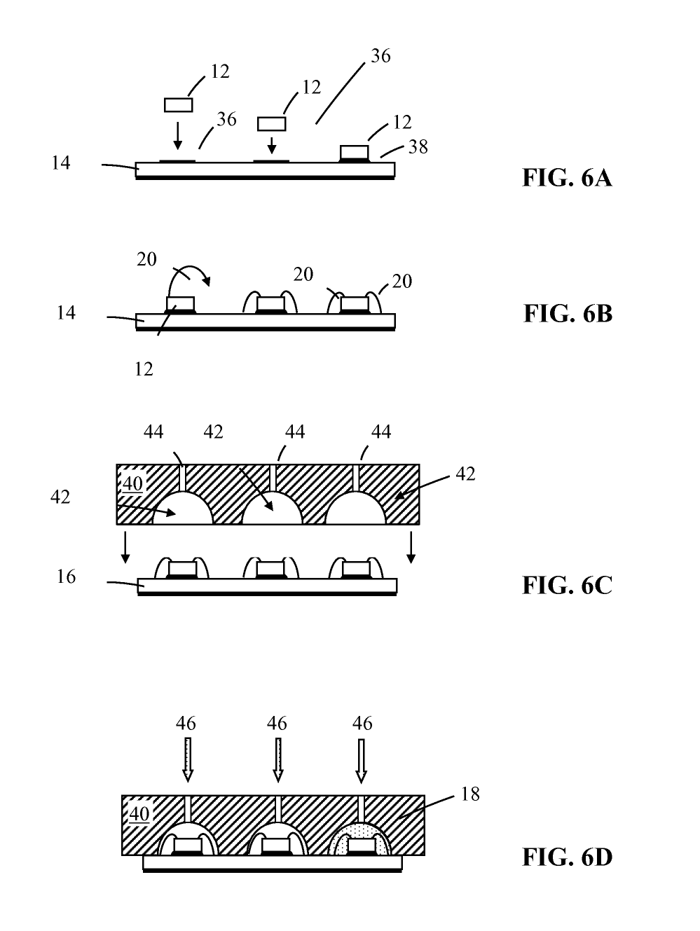

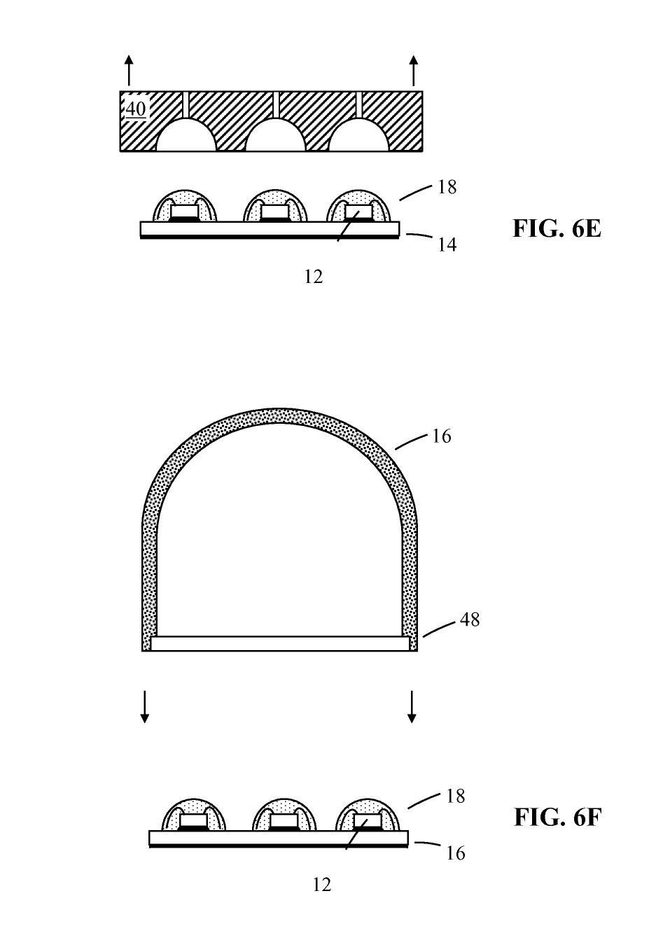

FIGS. 6A-6F illustrate an approach for manufacturing the LED package 10 of FIG. 1 according to some embodiments of the invention.

FIG. 6A illustrates LED chips 12 being assembled onto the substrate 14. The LED chips 12 are mounted (e.g. as a circular array) on an circular shaped MCPCB 14 on a respective thermal pad 36 on the upper surface of the MCPCB. The LED chips can be mounted to the thermal pads by soldering, reflow soldering, flip chip bonding or other techniques known in the art. Next, as shown in FIG. 6B, wire bonding 20 is performed to electrically connect the LED chips 12 to corresponding electrical connectors on the circuit board 14.

FIGS. 6C-6E illustrate a molding approach for forming encapsulant 18 over each of the LED chips 12. A mold 40 is provided which has an appropriately shaped and sized recess 42 that corresponds to the position of each LED chip 12. In the example illustrated each recess is substantially hemispherical in shape resulting in a hemispherical encapsulation 18. The mold 40 includes a filling port 44 for allowing each of the recesses to be filled. As shown in FIG. 6C, the mold 40 is properly positioned such that each interior recess 42 is appropriately located relative to its corresponding LED chip 12. Next, as illustrated in FIG. 6D, a curable liquid encapsulant 46 (which may be composed of an index matching gel or liquid polymer material such as silicone) is poured through the filling ports 44 to fill each of the interior recesses 42 of the mold 40. A curing process is then employed to cure the index matching gel or liquid material into its final solid form, e.g. by application of heat or UV light. As illustrated in FIG. 6E, the mold 40 is removed after the encapsulant has been cured. This leaves the encapsulant 18 individually encapsulating each of the LED chips 12.

As shown in FIG. 6F, the phosphor component 16 is then prepared for attachment to the circuit board 14 containing the LEDs 12. The phosphor component 16 may include a lip 48 that is configured to match the exterior profile of the circuit board 14. An adhesive material can be used to affix the phosphor component 16 to the circuit board 14. In some embodiments, the adhesive material forms a water-tight and hermetic seal that protects the interior of the LED package from exterior environmental contamination and/or degradation.

FIGS. 7A-7G illustrate an approach for manufacturing the LED package of FIG. 5 according to some embodiments of the invention.

FIG. 7A illustrates the LED chips 12 being assembled onto the circuit board 14. Each LED chip is mounted on the upper surface of the circuit board to a respective thermal pad 36. The LED chips can be mounted to the thermal pads by soldering, reflow soldering, flip chip bonding or other techniques known in the art. Next, as shown in FIG. 7B, wire bonding 20 is performed to electrically connect the LED chips 12 to electrical connectors on the circuit board 14.

A mold 40 is provided which has a recess 42 that exactly corresponds to the interior surface of the phosphor component 16. In the example shown the recess is substantially hemispherical in form. The mold 40 can includes a plurality of filling ports 44 to facilitate filling of the recess. As shown in FIG. 7C, the mold 40 is properly positioned on the circuit board over the LED chips 12. Next, as illustrated in FIG. 7D, a curable liquid encapsulant 46 is poured through the filling ports 44 to fill the interior recess 42 of the mold 40. A curing process is then employed to cure the encapsulant into its final solid form, e.g. by application of heat or UV light. As illustrated in FIG. 7E, the mold 40 is removed after the encapsulant has been cured.

As shown in FIG. 7F, the phosphor component 16 is then positioned to seat onto the circuit board 14 and to surround the solid optical medium 34. If the solid optical medium component 34 has been molded with the correct dimensions, then there should little or no air pockets/interfaces between the solid optical medium 34 and the component 16. If, however, manufacturing tolerances have resulted in the existence of any such air pockets/interfaces, then additional index matching gel may be introduced into the interior of the component 16 to eliminate the air pockets/interfaces. Alternatively and/or in addition the phosphor component 16 can comprise a resiliently deformable material (such as a silicone) to aid in good optical coupling between the mating surfaces of the optical medium and phosphor component. As illustrated in FIG. 7G, the phosphor component 16 is then affixed to the circuit board 14. An adhesive material can be used to affix the phosphor component 16 to the circuit board 14. In some embodiments, the adhesive material forms a water-tight and hermetic seal that protects the interior of the LED package from exterior environmental contamination and/or degradation.

It is noted that this embodiments illustrates a configuration whereby the outer edge 16a of the component 16 is aligned with the outer edge 14a of the circuit board 14, rather than extending beyond the outer edge 14a of the substrate/circuit board 14. This is in contrast the approach illustrated in FIG. 1A where the outer edge 16a of the component 16 extends beyond the outer edge 14a of the circuit board 14.

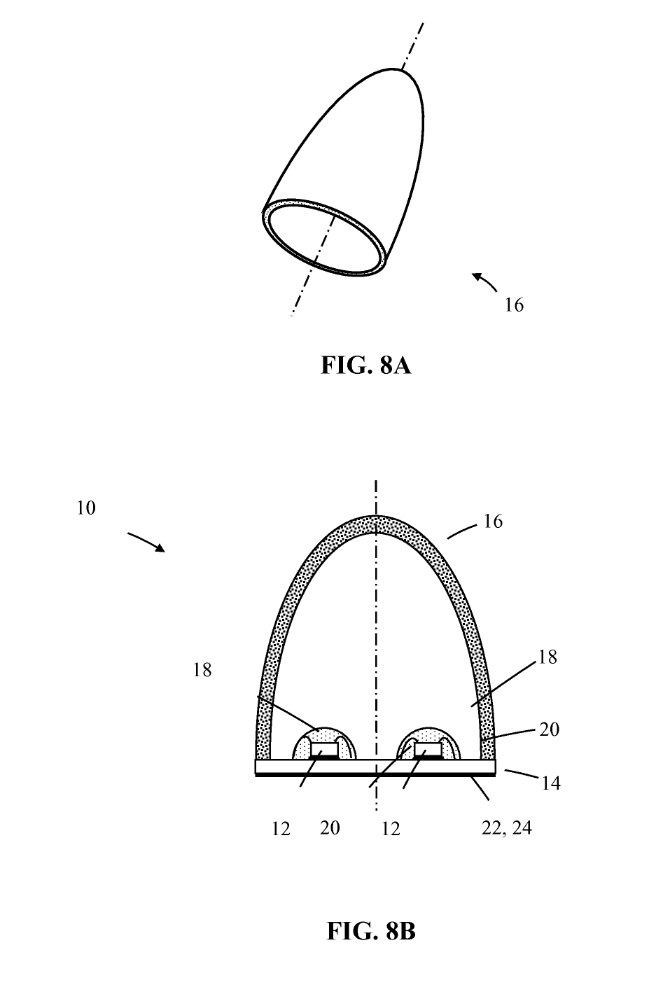

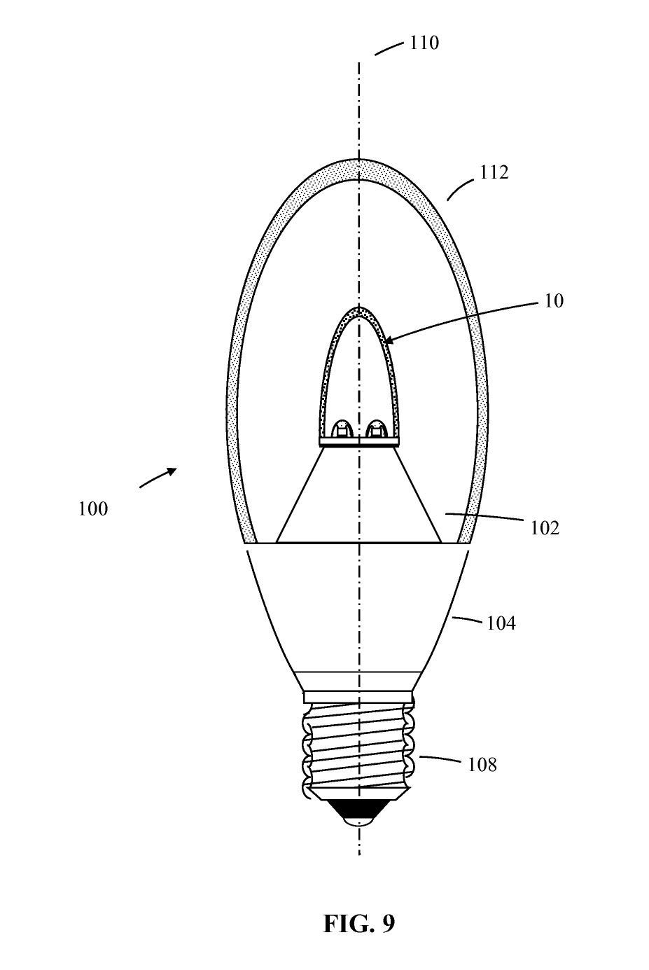

In each of the exemplary embodiments described the phosphor component 16 comprises a hollow component comprising a portion that is substantially hemispherical in form. In other embodiments it is contemplated that the phosphor component comprises hollow components of other shapes. For example FIGS. 8A and 8B respectively show a perspective view of a phosphor component and a schematic partial sectional view of an LED package utilizing such a component. As can be seen in the embodiment illustrated in FIG. 8A the phosphor component 16 comprises an hemi-ellipsoidal shell. The LED package 10 shown in FIG. 8B can find particular application in decorative lamps and bulbs such as candle bulbs as shown in FIG. 9. Such bulbs are often used in chandelier type applications.

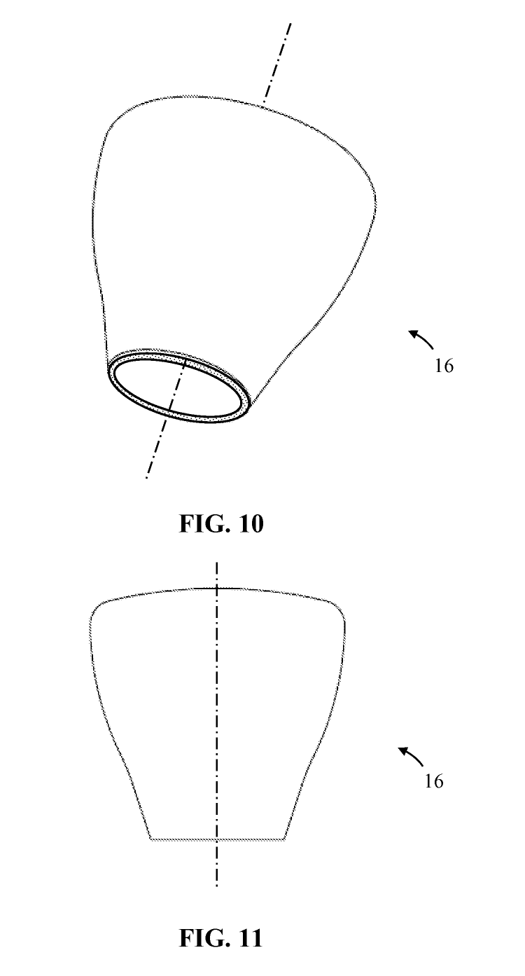

FIGS. 10 and 11 show a perspective view and side view of a further phosphor component 16. As shown in the figures the phosphor component 16 can comprise a generally dome/knob shaped shell in which the opening of the component is smaller than the maximum diameter. Such a component has a wide angle emission pattern making it ideally suited to omni-directional lamps such as A-19 type light bulbs.

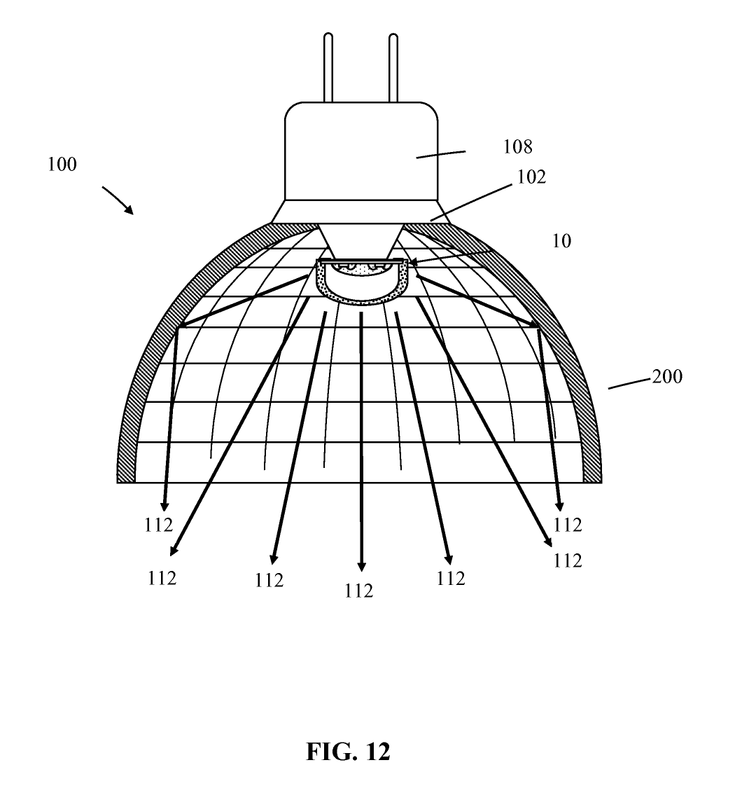

In the foregoing embodiments LED packages have been described in relation to their application within A-19 lamps. It will be appreciated that the LED packages of the invention find utility as light engines in other types of lamps such as reflector lamps, downlights and other types of lamps and luminaires. FIG. 12 is a schematic partial sectional view of an LED reflector lamp, such as an MR16 lamp utilizing an LED package of the invention. In this embodiment the LED package 10 is located at or near the focal point of a multifaceted reflector 200.

It will be appreciated that the invention is not limited to the exemplary embodiments described and that variations can be made within the scope of the invention.

What is claimed is:

1. An LED package, comprising:
a substrate having an outer substrate edge;
an array of one or more LEDs mounted on the substrate; and
a photoluminescence component comprising a photoluminescence material, wherein the photoluminescence component is remote from and encloses the array of one or more LEDs; the photoluminescence component having a surface with an outer component edge,
wherein the outer component edge is aligned with or extends beyond the outer substrate edge such that the package produces light emission angles from the photoluminescence component at greater than 180 degrees.

2. The LED package of claim 1, wherein the LED package is mountable as a self-contained unit onto a lamp platform.

3. The LED package of claim 1, wherein the array of one or more LEDs comprises at least one of a blue LED array, Red Blue LED Packaged Arrays, or chip on board (COB).

4. The LED package of claim 1, wherein the array of one or more LEDs is surrounded by an encapsulant.

5. The LED package of claim 4, wherein a solid optical medium fills an interior volume of the photoluminescence component to remove air interfaces between the array of one or more LEDs and the photoluminescence component.

6. The LED package of claim 1, further comprising a thermal pad configurable to thermally connect the LED package to a heat sink.

7. The LED package of claim 1, further comprising electrical connectors selected from the group consisting of: integrated electrical pads on a base of the package, a side of the package, on top of the package, and at least one of the electrical connectors is annular in shape.

8. The LED package of claim 1, wherein the array of one or more LEDs comprises a circular array and the substrate comprises a circular or annular shape wherein the diameter of the circular LED array is within 25% in size of the diameter of the substrate.

9. The LED package of claim 1, wherein the package produces the light emission angles from the photoluminescence component at greater than 250 degrees.

10. The LED package of claim 1, wherein a relatively small portion of the outer substrate extends beyond the outer component edge.

11. A lighting system, comprising:
an LED package, wherein the LED package comprises a substrate having a outer substrate edge, an array of one or more LEDs mounted on the substrate, and a photoluminescence component comprising a photoluminescence material;
the photoluminescence component is remote from and encloses the array of one or more LEDs;
the photoluminescence component having a surface with an outer component edge;
the outer component edge is aligned with or extends beyond the outer substrate edge such that the package produces light emission angles from the photoluminescence component at greater than 180 degrees; and
a lamp body upon the LED package is mounted as a unit.

12. The lighting system of claim 11, wherein a thermal pad on the LED package is mounted to an upper surface of a heat sink on the lamp body.

13. The lighting system of claim 11, wherein the array of one or more LEDs comprises at least one of a blue LED array, Red Blue LED Packaged Arrays, or chip on board (COB).

14. The lighting system of claim 11, in which the array of one or more LEDs is surrounded by an encapsulant.

15. The lighting system of claim 14, wherein a solid optical medium fills an interior volume of the photoluminescence component to remove air interfaces between the array of one or more LEDs and the photoluminescence component.

16. The lighting system of claim 11, further comprising a thermal pad configurable to thermally connect the LED package to a heat sink.

17. The lighting system of claim 11, further comprising electrical connectors selected from the group consisting of: integrated electrical pads on a base of the package, a side of the package, on top of the package and at least one of the electrical connectors is annular in shape.

18. The lighting system of claim 11, wherein the array of one or more LEDs comprises a circular array and the substrate comprises a circular or annular shape wherein the diameter of the circular LED array is within 25% in size of the diameter of the substrate.

19. The lighting system of claim 11, wherein light emission angles are producible at greater than 250 degrees.

20. The lighting system of claim 11, wherein a relatively small portion of the outer substrate extends beyond the outer component edge.
